(19) United States
(12) Patent Application Publication
(10) Pub. No.: US 2024/0297094 A1
(43) Pub. Date: Sep. 5, 2024

(54) HEAT DISSIPATION STRUCTURE AND PORTABLE INFORMATION DEVICE

(71) Applicant: Lenovo (Singapore) Pte. Ltd., Singapore (SG)

(72) Inventors: Ryota Watanabe, Kanagawa (JP); Junki Hashiba, Kanagawa (JP); Akinori Uchino, Kanagawa (JP); Takuroh Kamimura, Kanagawa (JP)

(73) Assignee: Lenovo (Singapore) Pte. Ltd., Singapore (SG)

(21) Appl. No.: 18/411,320

(22) Filed: Jan. 12, 2024

(30) Foreign Application Priority Data
Mar. 1, 2023 (JP) 2023-031115

(51) Int. Cl. H01L 23/373; G06F 1/20; H01L 23/42; H05K 7/20

(52) U.S. Cl. CPC H01L 23/3737; G06F 1/206; H01L 23/42; H05K 7/20463

(57) ABSTRACT

A heat dissipation structure, of a semiconductor chip that includes a substrate and a die provided on a top surface of the substrate, includes: a heat dissipator provided along a surface of the die; a liquid metal interposed between the die and the heat dissipator; and a thermal putty interposed between the substrate and the heat dissipator in a state of sealing therebetween and surrounding the die.

### CROSS-REFERENCE TO RELATED APPLICATIONS

This application claims priority to Japanese Patent Application No. 2023-031115 filed on May 1, 2023, the contents of which are hereby incorporated herein by reference in their entirety.

### TECHNICAL FIELD

The present invention relates to a heat dissipation structure and a portable information device.

### BACKGROUND

Portable information devices such as laptop PCs include semiconductor chips such as GPUs and CPUs. A GPU or a CPU is shaped to have a substrate which is a part to be mounted on a board and a rectangular die provided on the surface of the substrate.

A semiconductor chip such as a GPU or a CPU is a heating element, and requires heat dissipation depending on its power consumption (especially when highly loaded). As a means of dissipating heat from the GPU or CPU, a heat dissipator such as a vapor chamber, a heat spreader, or a heat sink may be used, and brought into contact with the surface of the die to diffuse heat. A fluid such as thermally conductive grease may be interposed between the die and the heat dissipator as a thermal interface material (TIM), in order to efficiently transfer heat.

There is a concern that such a fluid may seep into the surroundings from between the die and the heat exchanger plate due to vibration and the like. Hence, according to Japanese Unexamined Patent Application Publication No. 2020-088273, a wall member surrounding the die is provided between the substrate and the heat exchanger plate. The wall member is cushioning silicone rubber or grease.

Recently, liquid metal is sometimes used as a fluid TIM. Liquid metal has higher thermal conductivity than thermally conductive grease, and can effectively transfer heat from the die to the heat dissipation component. Meanwhile, liquid metal has unique characteristics different from thermally conductive grease, etc., and in the case where liquid metal is used as a TIM, special measures are needed to prevent the liquid metal from leaking into the surroundings.

### SUMMARY

One or more embodiments of the present invention provide a heat dissipation structure and portable information device suitable for, in the case where liquid metal is used as a TIM, preventing the liquid metal from leaking into the surroundings.

A heat dissipation structure according to one or more embodiments of the present invention is a heat dissipation structure of a semiconductor chip that includes a substrate and a die provided on a top surface of the substrate, the heat dissipation structure including: a heat dissipator provided along a surface of the die; a liquid metal interposed between the die and the heat dissipator; and a thermal putty interposed between the substrate and the heat dissipator in a state of sealing therebetween and surrounding the die. A portable information device according to one or more embodiments of the present invention includes the above-described heat dissipation structure.

The above-described aspects of the present invention are suitable for, in the case where liquid metal is used as a TIM, preventing the liquid metal from leaking into the surroundings.

### BRIEF DESCRIPTION OF THE DRAWINGS

FIG. 1 is an exploded perspective view illustrating a heat dissipation structure and part of a portable information device according to one or more embodiments of the present invention.

FIG. 2 is a perspective view of a CPU.

FIG. 3 is a schematic cross-sectional side view of the heat dissipation structure according to one or more embodiments.

### DETAILED DESCRIPTION

Embodiments of a heat dissipation structure and a portable information device according to the present invention will be described in detail below with reference to the drawings. Note that the present invention is not limited by these embodiments.

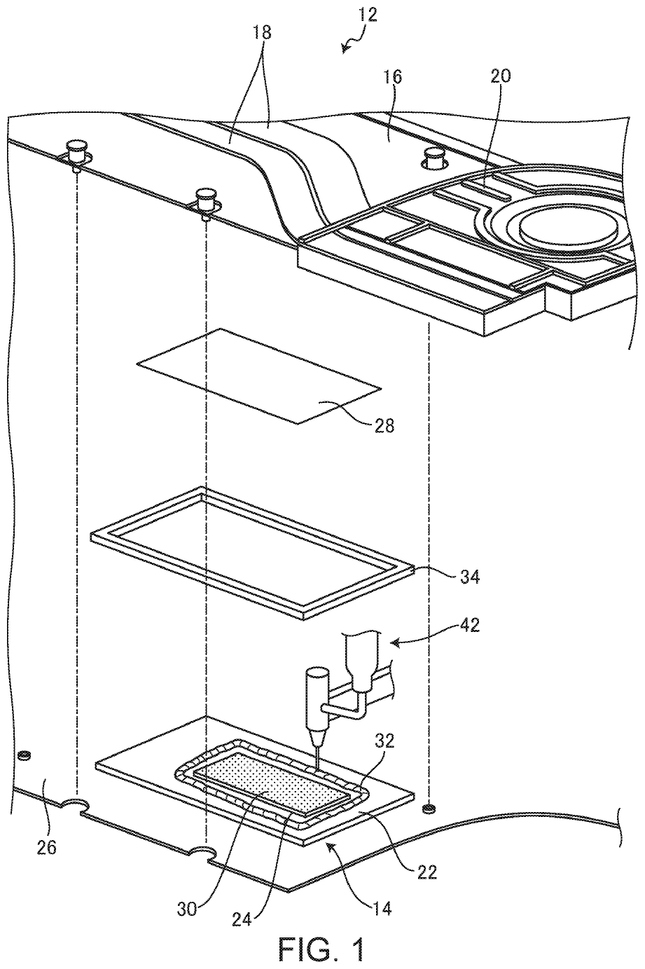

FIG. 1 is an exploded perspective view illustrating a heat dissipation structure 10 and part of a portable information device 12 according to one or more embodiments of the present invention.

The portable information device 12 is, for example, a laptop PC, a tablet terminal, or a smartphone, and includes a central processing unit (CPU) 14. The CPU (semiconductor chip) 14 performs high-speed computation and generates heat accordingly, so that heat dissipation is needed. The portable information device 12 includes a vapor chamber 16 (heat dissipator) as a heat dissipation means for the CPU 14. The heat dissipation structure 10 may be used in an electronic device such as a stationary desktop computer, but is suitable for use in the portable information device 12 that can be subjected to vibration or impact when carried.

The vapor chamber 16 is a plate-shaped member obtained by joining the edges of two metal plates (e.g. copper plates) to form a closed space inside, and can diffuse heat with high efficiency by the phase change of a working fluid enclosed in the closed space. A wick that delivers the condensed working fluid by capillary action is located in the closed space of the vapor chamber 16.

Two substantially parallel heat pipes 18 are provided in the vapor chamber 16. The heat pipes 18 have their ends connected to a fan 20. Each heat pipe 18 is a thin flat metal pipe having a closed space formed inside, in which a working fluid is enclosed. A wick is located in the heat pipe 18, as in the vapor chamber 16. The vapor chamber 16 is basically parallel to a surface 24a of a die 24.

A heat exchanger plate (heat dissipator) 28 is provided in the part of the vapor chamber 16 facing the die 24 of the CPU 14. The heat exchanger plate 28 is thermally connected to the die 24 via a liquid metal 30. The heat exchanger plate 28 is made of a material having excellent heat transference, and is, for example, a copper plate. The heat exchanger plate 28 has a thickness of about 0.3 mm to 2 mm, for example. The heat exchanger plate 28 is rectangular, and has an area that is slightly larger than the die 24 and is smaller than a substrate 22. The heat exchanger plate 28 is fixed to the vapor chamber 16 by soldering or the like, and the heat exchanger plate 28 and the vapor chamber 16 substantially constitute a heat dissipator. The heat exchanger plate 28 may be subjected to surface treatment such as nickel plating. The heat exchanger plate 28 may be omitted depending on design conditions.

The heat dissipation means for the heating element such as the CPU 14 is not limited to the vapor chamber 16, and various heat dissipators are applicable. Examples of heat dissipators include metal plates with high thermal conductivity such as copper and aluminum, graphite plates, heat lanes, and heat sinks.

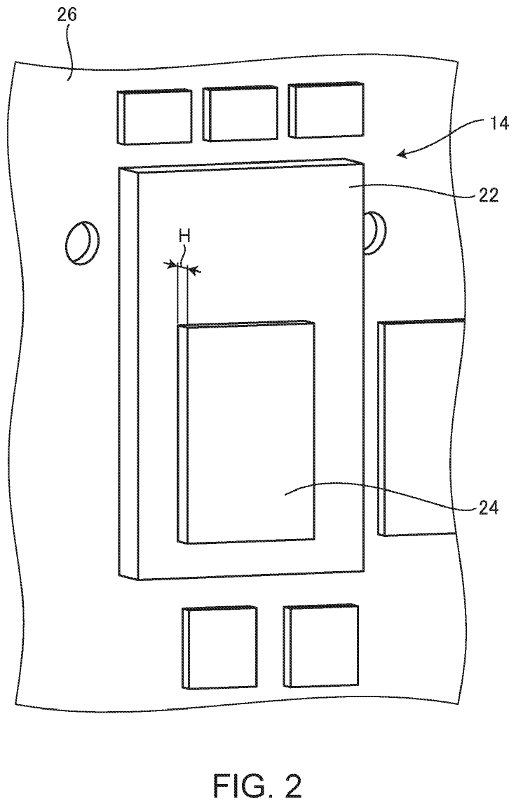

FIG. 2 is a perspective view of the CPU 14. The components of the heat dissipation structure 10 are omitted in FIG. 2. The CPU 14 includes the substrate 22 and the die 24. The substrate 22 is a thin plate-shaped portion mounted on a board 26, and is rectangular in a plan view. The die 24 is a portion including an arithmetic circuit, and slightly protrudes from the top surface of the substrate 22. The height H of the die 24 is typically about 0.3 mm to 1.0 mm. The die 24 has a rectangular shape smaller than that of the substrate 22 in a plan view, and is somewhat off-centered on the top surface of the substrate 22. The substrate 22 and the die 24 may be square.

The CPU 14 is one of the components that generate the most heat in the portable information device 12, and the die 24 in particular generates heat. The portable information device 12 may include a graphics processing unit (GPU). The GPU includes a substrate and a die as in the CPU, and the heat dissipation structure 10 can be used for the GPU. The heat dissipation structure 10 can also be used for heat dissipation of a semiconductor chip other than the CPU 14 or the GPU or heat dissipation of any other electric component that generates heat.

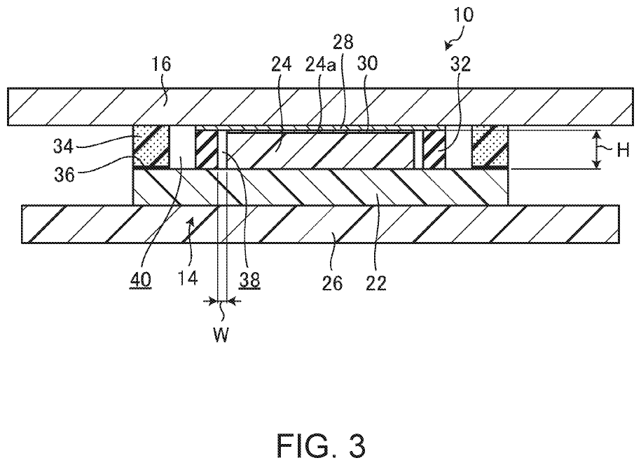

FIG. 3 is a schematic cross-sectional side view of the heat dissipation structure 10 according to one or more embodiments of the present invention. The heat dissipation structure 10 includes the vapor chamber 16, the heat exchanger plate 28, the liquid metal 30 interposed between the surface 24a of the die 24 and the heat exchanger plate 28, a thermal putty 32 pressed and interposed between the substrate 22 and the heat exchanger plate 28 in a state of being in close contact with the substrate 22 and the heat exchanger plate 28 to seal the space therebetween and surrounding the die 24, and a sponge 34 pressed and interposed between the substrate 22 and the vapor chamber 16 in a state of sealing the space therebetween and surrounding the thermal putty 32. A narrow first gap 38 is formed between the die 24 and the thermal putty 32. A second gap 40 is formed between the thermal putty 32 and the sponge 34.

The liquid metal 30 is a metal that is liquid basically at room temperature. The liquid metal 30 is liquid at least at temperatures in a normal use state in which the board 26 of the portable information device 12 is energized and the CPU 14 is in operation. Since the liquid metal 30 is metal, it has excellent thermal conductivity and electrical conductivity. For example, the liquid metal 30 is mainly made of gallium. In FIG. 1, the application range of the liquid metal 30 is indicated by dots.

The sponge 34 is provided on the peripheral part of the substrate 22 and protrudes upward. The sponge 34 is a frame body, and coincides with the substrate 22 at the outer edges. The sponge 34 is slightly higher than the die 24 in a natural state without external force, and is appropriately compressed by the vapor chamber 16 and the heat exchanger plate 28 in an assembled state of the heat dissipation structure 10. The sponge 34 is adhered and fixed to the surface of the substrate 22 by adhesive tape 36 of the same shape in a plan view.

The thermal putty 32 is a putty material that has thermal conductivity and is applied to prevent the liquid metal 30 from leaking into the surroundings. The thermal putty 32 is neither solid nor elastic, and therefore has low resilience and does not generate a large reaction force when compressed by the substrate 22 and the heat exchanger plate 28. This ensures that the heat exchanger plate 28 is in contact with the liquid metal 30 and is thermally connected to the surface 24a of the die 24 via the liquid metal 30. The thermal putty 32 has low resilience, so that vibration and impact are absorbed between the substrate 22 and the heat exchanger plate 28. Since the thermal putty 32 is not solid, it has high followability and adhesion and has high sealing performance and heat conduction performance. Since the thermal putty 32 is a putty material, it has higher viscosity than grease and has shape retainability with low fluidity, and accordingly its sealing performance is maintained with little shape change even after the heat dissipation structure 10 is assembled. To achieve such effect by low fluidity, the viscosity of the thermal putty 32 is desirably 2500 (Pa·s) or more as measured by ASTM D1824 1.0 (1/S).

As a result of the thermal putty 32 having shape retainability, the width W of the first gap 38 can be set with considerable accuracy. The first gap 38 is formed to be appropriately narrow, and may be set to about 0.5 mm to 1.0 mm in the case of the die 24 of standard size and the liquid metal 30 of commonly used type. The application amount of the liquid metal 30 is typically controlled by an automatic machine, but the amount of the liquid metal 30 applied is increased to some extent in consideration of errors. As a result, a small excess amount of the liquid metal 30 pressed from above by the vapor chamber 16 and the heat exchanger plate 28 protrudes from the surface 24a of the die 24, but basically stays in the first gap 38 without leaking outside. Even if the liquid metal 30 leaks out of the first gap 38 due to an unexpected situation, the liquid metal 30 stays in the second gap 40 formed by the sponge 34 and is kept from leaking outside the range of the substrate 22. The volume of the second gap 40 is set to be sufficiently larger than the volume of the first gap 38. Therefore, even if the leakage amount of the liquid metal 30 increases, the leaked liquid metal 30 can be stored in the second gap 40.

Thermally conductive grease typically has a viscosity of 1000 (Pa·s) or less, and does not have shape retainability like the thermal putty 32. With thermally conductive grease, it is difficult to stably seal the range of the height H between the substrate 22 and the heat exchanger plate 28 so as to withstand vibration and the like, and it is difficult to accurately form the narrow first gap 38 with the die 24.

Although the thermal putty 32 is low in fluidity, it has the fluidity of a putty material, and can be auto-injected by a dispenser 42 as schematically illustrated in FIG. 1.

The thermal putty 32 is applied by the dispenser 42 with considerable accuracy. Even if the thermal putty 32 deforms due to an unexpected situation during assembly or the like and part of the thermal putty 32 enters between the die 24 and the heat exchanger plate 28, no thermal resistance occurs between the die 24 and the heat exchanger plate 28 and good thermal conductivity is ensured because the thermal putty 32 is thermally conductive. To achieve such effect by thermal conductivity, the thermal conductivity of the thermal putty 32 is desirably 3.0 (W/m·K) or more as a typical value of thermally conductive material as measured by the hot disk method.

The thermal putty 32 is inert to metals. Therefore, even if the liquid metal 30 enters the first gap 38 and comes into contact with the thermal putty 32, the thermal putty 32 does not chemically react with gallium, which is the main component of the liquid metal 30, to cause corrosion. Moreover, the thermal putty 32 itself does not change in quality and maintains its sealing effect. While thermally conductive grease contains an aluminum filler and may corrode the liquid metal 30, the thermal putty 32 has no such problem.

Since the thermal putty 32 is one-component and non-curing type, no curing operation is needed, and there is no deterioration in sealing performance due to curing over time. The thermal putty 32 contains a silicone rubber component and has properties such as heat resistance, cold resistance, and electrical insulation. Since the thermal putty 32 has electrical insulation property, even if part of the thermal putty 32 peels off and comes into contact with an electronic component on the board 26, no short circuit occurs. In the case where the heat exchanger plate 28 is omitted, the thermal putty 32 is interposed between the substrate 22 and the vapor chamber 16. In one or more embodiments, however, the thermal putty 32 is interposed between the substrate 22 and the heat exchanger plate 28 rather than between the substrate 22 and the vapor chamber 16. In this way, the width W of the first gap 38 can be set narrowly. Moreover, as a result of the thickness of the thermal putty 32 decreasing by the thickness of the heat exchanger plate 28, stability and thermal conductivity can be enhanced and the amount of the thermal putty 32 used can be reduced. The thermal putty 32 may be provided in a range from the heat exchanger plate 28 to the vapor chamber 16. An example of the thermal putty 32 is SARCON SPG-30B manufactured by Fuji Polymer Industries Co., Ltd.

In the heat dissipation structure 10 according to one or more embodiments, the liquid metal 30 used as a TIM has higher fluidity than thermally conductive grease used as a TIM. Accordingly, particularly in the case where the heat dissipation structure 10 is used in the portable information device 12, the liquid metal 30 is likely to leak from between the die 24 and the heat exchanger plate 28 due to vibration when the portable information device 12 is being carried. However, since the die 24 is covered with the thermal putty 32 having shape retainability, the liquid metal 30 is basically prevented from leaking out of the first gap 38. Thus, the liquid metal 30 is mostly retained on the surface 24a of the die 24, so that heat dissipation performance is maintained and stability is enhanced. Even if the liquid metal 30 leaks out of the first gap 38, the liquid metal 30 is contained in the second gap 40 without diffusing to the board 26 because of two-stage sealing by the sponge 34. The heat dissipation structure 10 and the portable information device 12 are therefore suitable for, in the case where the liquid metal 30 is used as a TIM, preventing the liquid metal 30 from leaking into the surroundings, with it being possible to improve reliability.

The thermal putty 32 has shape retainability but has, as a characteristic of patty material, a certain degree of fluidity so as to be injectable by the dispenser 42. The thermal putty 32 thus has lower resilience than elastic bodies such as rubber material and hardly generates a reaction force against the substrate 22 and the heat exchanger plate 28. While the liquid metal 30 is liquid and forms a thin layer, the heat exchanger plate 28 can reliably contact the liquid metal 30 because the heat exchanger plate 28 is not subjected to any reaction force from the thermal putty 32.

The first gap 38 may be omitted by reducing the amount of the liquid metal 30 applied to the surface 24a of the die 24, depending on design conditions. In the case where an electronic component such as a capacitor is provided on the top surface of the substrate 22, the electronic component may be protected by a coating material such as an ultraviolet curable coating. The present invention is not limited to the embodiments described above, and changes can be made freely without departing from the gist of the present invention.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### DESCRIPTION OF SYMBOLS

10 heat dissipation structure
12 portable information device
20 fan
22 substrate
24 die
28 heat exchanger plate
30 liquid metal
32 thermal putty
34 sponge
38 first gap
40 second gap
42 dispenser

What is claimed is:

1. A heat dissipation structure of a semiconductor chip that includes a substrate and a die provided on a top surface of the substrate, the heat dissipation structure comprising:
a heat dissipator provided along a surface of the die;
a liquid metal interposed between the die and the heat dissipator; and
a thermal putty interposed between the substrate and the heat dissipator in a state of sealing therebetween and surrounding the die.

2. The heat dissipation structure according to claim 1, wherein a gap is formed between the thermal putty and the die.

3. The heat dissipation structure according to claim 1, wherein the thermal putty has low fluidity that allows maintaining a shape as a sealing material, and inertness to metals.

4. The heat dissipation structure according to claim 3, wherein the thermal putty has a thermal conductivity of 3.0 W/m·K or more and a viscosity of 2500 Pa·s or more.

5. The heat dissipation structure according to claim 1, comprising a sponge interposed between the substrate and the heat dissipator in a state of sealing therebetween and surrounding the thermal putty with a gap in between.

6. The heat dissipation structure according to claim 1, wherein the heat dissipator includes a heat exchanger plate thermally connected to the die via the liquid metal, and
wherein the thermal putty is provided between the substrate and the heat exchanger plate.

7. A portable information device comprising the heat dissipation structure according to claim 1.
